(19) United States
(12) Patent Application Publication
(10) Pub. No.: US 2025/0299914 A1
(43) Pub. Date: Sep. 25, 2025

(54) SEMICONDUCTOR PATTERN MEASUREMENT METHOD, AND SEMICONDUCTOR DEVICE MANUFACTURING METHOD INCLUDING THE SAME

(71) Applicant: Samsung Electronics Co., Ltd., Suwon-si (KR)

(72) Inventors: Seungwon SONG, Suwon-si (KR); Bongkeun KIM, Suwon-si (KR); Dawoon CHOI, Suwon-si (KR); Kihyun KIM, Suwon-si (KR)

(73) Assignee: Samsung Electronics Co., Ltd., Suwon-si (KR)

(21) Appl. No.: 18/921,269

(22) Filed: Oct. 21, 2024

(30) Foreign Application Priority Data
Mar. 21, 2024 (KR) 10-2024-0039281

(51) Int. Cl. H01J 37/28; H01J 37/22

(52) U.S. Cl. CPC H01J 37/28; H01J 37/222; H01J 2237/2817

(57) ABSTRACT

A semiconductor pattern measurement method includes extracting patterns for each type from patterns of a full-chip stored in a database, assigning an identification (ID) to the patterns, forming a two-dimensional grid structure on the full-chip, sorting the patterns in order from a pattern of the ID with a lowest frequency to a pattern of the ID with a highest frequency, assigning the sorted patterns to corresponding grids of the two-dimensional grid structure, and measuring the patterns assigned to the grids. In the measuring of the patterns, a separation distance is set between patterns that are measured based on the grids.

### CROSS-REFERENCE TO RELATED APPLICATION

This application is based on and claims priority under 35 U.S.C. § 119 to Korean Patent Application No. 10-2024-0039281, filed on Mar. 21, 2024, in the Korean Intellectual Property Office, the disclosure of which is incorporated by reference herein in its entirety.

### BACKGROUND

Various example embodiments relate to a semiconductor pattern measurement method, and particularly, to a semiconductor pattern measurement method using an electron beam of a scanning electron microscope (SEM) or a device similar thereto, and/or a semiconductor device manufacturing method including the semiconductor pattern measurement method.

The SEM is a type of electronic microscope that scans a surface of a sample with an electron beam and images the scanned surface. For example, a SEM analysis method refers to a method of emitting electrons from a high-speed electron gun and, as the electrons collide and interact with a surface of a sample, detecting and analyzing particles such as secondary electrons that bounce out of the sample. Recently, in measurement using a SEM or using electron beams similar thereto, a measurement region has often been damaged because high voltage electron beams overlap each other and are emitted to the measurement area.

### SUMMARY

Various example embodiments provide a semiconductor pattern measurement method of measuring all required or desired patterns while preventing or reducing metrology damage, and/or a semiconductor device manufacturing method including the semiconductor pattern measurement method.

In addition, problems to be solved or improved upon by inventive concepts are not limited to the problems described above, and other problems may be clearly understood by those of ordinary skill in the art from the description below.

According to some example embodiments, a semiconductor pattern measurement method includes extracting patterns for each type from patterns of a full-chip stored in a database, assigning an identification (ID) to the patterns, forming a two-dimensional grid structure on the full-chip, sorting the patterns in order from a pattern of the ID with a lowest frequency to a pattern of the ID with a highest frequency, assigning the sorted patterns to corresponding grids of the two-dimensional grid structure, and measuring the patterns assigned to the grids. In the measuring of the patterns, a separation distance is set between patterns that are measured based on the grids.

Alternatively or additionally according to various example embodiments, a semiconductor pattern measurement method includes extracting, by a pattern reduction tool, patterns for each type from patterns of one layer among multiple layers of a full-chip stored in a database, assigning an identification (ID) to the patterns, forming a two-dimensional grid structure on the full-chip, sorting the patterns in order from a pattern of the ID with a lowest frequency to a pattern of the ID with a highest frequency, assigning the sorted patterns to corresponding grids of the two-dimensional grid structure, and measuring, by a scanning electron microscope (SEM), a photoresist (PR) pattern corresponding to the patterns assigned to the grids, wherein, in the assigning of the extracted patterns to the corresponding grids, in response to there being patterns of IDs not assigned to the grids, the patterns of the ID assigned to the grids are classified as selected patterns, and the patterns of the IDs not assigned to the grids are classified as non-selected patterns, and distances between the selected patterns are calculated for each ID of the non-selected patterns, and a farthest non-selected pattern is assigned to the grid.

Alternatively or additionally according to various example embodiments, a semiconductor device manufacturing method includes extracting, by a pattern reduction tool, patterns for each type from patterns of one layer among multiple layers of a full-chip stored in a database, assigning an identification (ID) to the patterns, forming a two-dimensional grid structure on the full-chip, sorting the patterns in order from a pattern of the ID with a lowest frequency to a pattern of the ID with a highest frequency, assigning the sorted patterns to corresponding grids of the two-dimensional grid structure, forming photoresist (PR) patterns corresponding to the patterns of the one layer, measuring the PR patterns corresponding to the patterns assigned to the grids, determining whether the PR patterns are normal, and performing a subsequent semiconductor process in response to the PR patterns being normal. In the measuring of the PR patterns, a separation distance is set between the PR patterns measured based on the grids.

### BRIEF DESCRIPTION OF THE DRAWINGS

Various example embodiments will be more clearly understood from the following detailed description taken in conjunction with the accompanying drawings in which:

FIG. 1 is a flowchart schematically illustrating a semiconductor pattern measurement method according to some example embodiments;

FIG. 2A to FIG. 2D are conceptual diagrams illustrating the semiconductor pattern measurement method of FIG. 1 in conjunction with a full-chip;

FIG. 3A to FIG. 3C are ID tables specifically illustrating an operation of assigning an identification (ID) and an operation of assigning the ID to a grid, which are included in the semiconductor pattern measurement method of FIG. 1;

FIG. 4 is a conceptual diagram illustrating an operation of forming a two-dimensional grid structure which is included in the semiconductor pattern measurement method of FIG. 1;

FIG. 5A to FIG. 5C are ID tables and a conceptual diagram illustrating a method of assigning patterns of IDs to grids when there are patterns of IDs not assigned to the grids, in relation to an operation of assigning the patterns of IDs to the grids, in the semiconductor pattern measurement method of FIG. 1;

FIG. 6A and FIG. 6B are ID tables illustrating exceptional cases of the method of assigning patterns of IDs to grids through a distance calculation of FIG. 5A to FIG. 5C;

FIG. 7A and FIG. 7B are conceptual views and enlarged views illustrating distributions of patterns of measurement targets, in a semiconductor pattern measurement method according to a comparative embodiment and a semiconductor pattern measurement method according to various example embodiments; and

FIG. 8 is a flowchart schematically illustrating a semiconductor device manufacturing method including a semiconductor pattern measurement method, according to some example embodiments.

### DETAILED DESCRIPTION OF VARIOUS EXAMPLE EMBODIMENTS

Hereinafter, various example embodiments are described in detail with reference to the attached drawings. The same reference numerals are used for the same components in the drawings, and redundant descriptions thereof are omitted.

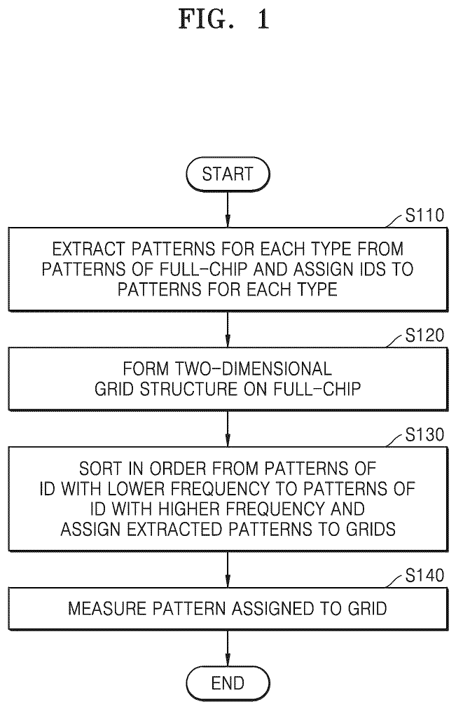

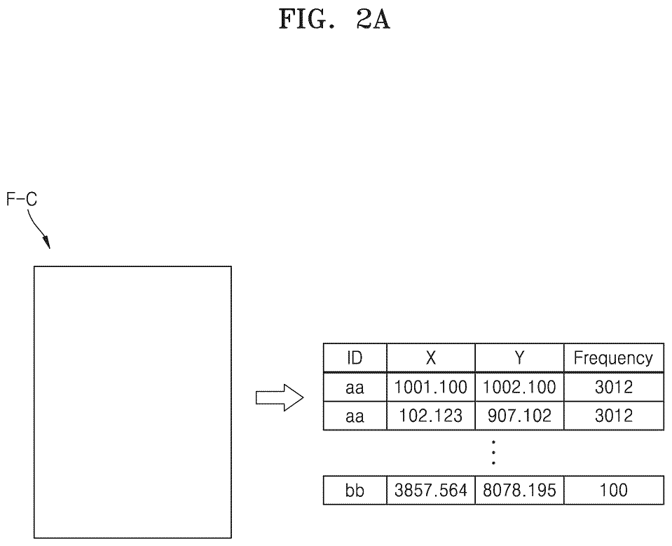

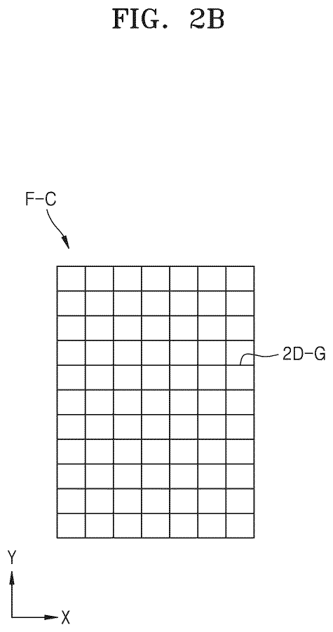

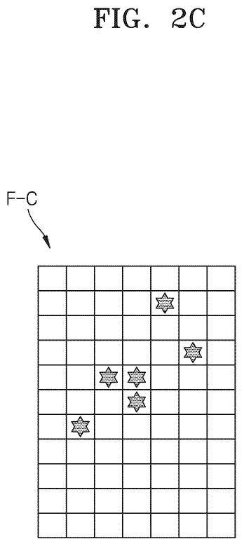

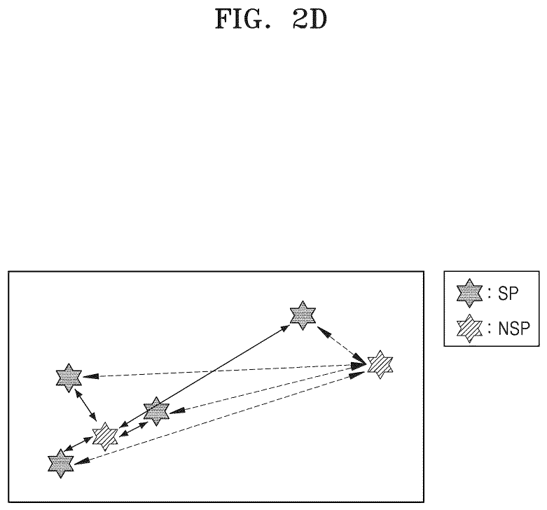

FIG. 1 is a flowchart schematically illustrating a semiconductor pattern measurement method according to some example embodiments, and FIG. 2A to FIG. 2D are conceptual diagrams illustrating the semiconductor pattern measurement method of FIG. 1 in conjunction with a full-chip.

Referring to FIG. 1 and FIG. 2A, in a semiconductor pattern measurement method according to various example embodiments, patterns for each type may be extracted from patterns of a full-chip F-C stored in a database (DB) and assign IDs to the patterns for each type (S110). The database DB may be a database associated with a graphics design system, such as a GDSII system; example embodiments are not limited thereto. Here, the full-chip F-C indicates one chip, although example embodiments are not limited thereto. In some cases, the full-chip F_C may be a concept that emphasizes entirety of the one chip instead of some layers or a part of the one chip. In general, the full-chip F-C may include multiple layers such as multiple active area layers, multiple gate layers, multiple metal layers, multiple contact layers, and/or multiple via layers, and each of the multiple layers may include many patterns. For example, a critical layer may also include more than 100 million patterns or a polygon. For reference, the polygon is a similar concept to a pattern, but strictly speaking, one pattern corresponds to one polygon or may be divided into multiple polygons.

In addition, extraction of patterns for each type may be performed on patterns of one layer of the full-chip F-C. In some examples, the extraction of patterns for each type may be performed by using a pattern reduction tool. The pattern reduction tool may include at least one of, for example, a clustering tool, a pattern matching tool, and an optical rule check (ORC) tool. The pattern reduction tool is not limited to the tools described above. For example, the pattern reduction tool may include all types of tools that may classify and extract the patterns for each type.

In some example embodiments, clustering may refer to grouping data for each of similar characteristics and dividing the entire data into several clusters. The clustering tool may include or be based on, for example, one or more of a hierarchical clustering tool, a K-mean clustering tool, a density-based spatial clustering applications with noises (DBSCAN) tool, a state of nature reduction (SONR) tool, and so on. However, the clustering tool is not limited to the clustering tools described above.

Pattern matching may refer to a method of extracting and classifying matching patterns by comparing patterns for each particular (e.g., preset) type with patterns of any one layer of the full-chip F-C. ORC may refer to a method of detecting a pattern at risk of defect in optical proximity correction (OPC) simulation or a warning method. Here, OPC may refer to a method of correcting or improving a design layout of patterns on a mask to reduce an optical proximity effect (OPE) occurring between adjacent patterns during an exposure process as patterns are reduced.

FIG. 2A illustrates an ID table in which IDs are assigned to patterns for each type extracted from patterns of one layer of the full-chip F-C. The ID table may include IDs, X coordinates and Y coordinates of patterns (such as a center or bottom-left coordinate of the patterns), and the frequency of the IDs.

As may be seen from the ID table, one ID may include multiple patterns. For example, an ID aa may include 3012 patterns. In addition, positions of patterns of the same ID may be different from each other. For example, it can be seen that a coordinate value of a pattern of the uppermost ID aa is different from a coordinate value of a pattern of the second ID aa. In some examples, in the ID table of FIG. 2A, IDs with higher frequencies may be placed above and IDs with lower frequencies may be placed below. Therefore, although not shown in the ID table of FIG. 2A, an ID including fewer than 100 patterns may written under an ID bb. However, the order of IDs included in the ID table is not limited to the method described above.

Referring to FIG. 1 and FIG. 2B, after IDs are assigned the patterns for each type, a two-dimensional grid structure 2D-G is formed on the full-chip F-C. For example, as illustrated in FIG. 2B, the two-dimensional grid structure 2D-G having equal intervals in the X direction and Y direction may be formed on the full-chip F-C. For example, when an area of the full-chip F-C is denoted as mm, two-dimensional grids of 10 mm*10 mm may be formed on the full-chip F-C by dividing by 10 in the X direction and Y direction. Size of the grids are not limited to 10 mm*10 mm.

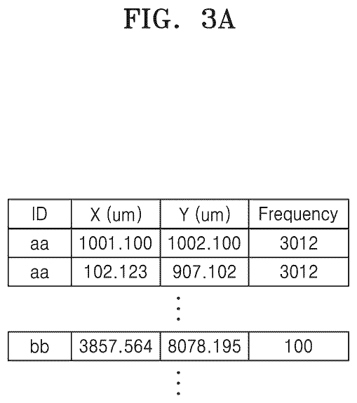

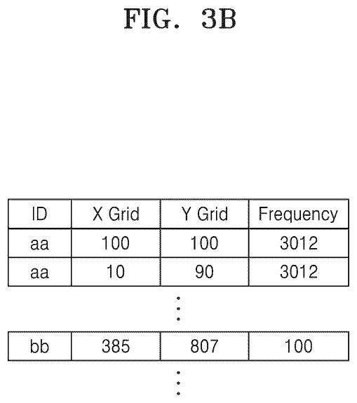

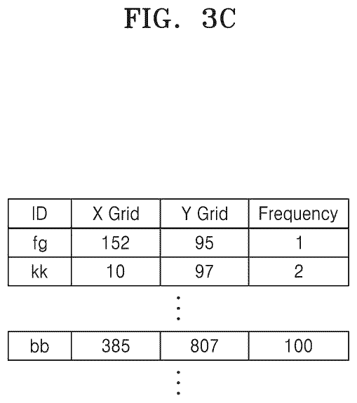

While the two-dimensional grid structure 2D-G is formed on the full-chip F-C, distance coordinates of patterns on the ID table may be converted into grid coordinates. Rounding, e.g., rounding down may be applied to the conversion of distance coordinates to grid coordinates. However, not only rounding down may be applied to the conversion of distance coordinates to grid coordinates. For example, rounding up or rounding at a center may be applied to the conversion of distance coordinates to grid coordinates. The conversion of distance coordinates to grid coordinates is described in more detail with reference to FIG. 3A to FIG. 3C.

Referring to FIG. 1 and FIG. 2C, after the two-dimensional grid structure 2D-G is formed on a full-chip F-C, patterns are extracted or sorted in order from the patterns of an ID with a lower frequency to the pattern of an ID with a higher frequency, and the extracted patterns are assigned to grids of a corresponding two-dimensional grid structure (S130). For example, patterns of an ID with a lower frequency are first assigned to grids of the corresponding two-dimensional grid structure, and patterns of an ID with a higher frequency are gradually assigned to grids of the corresponding two-dimensional grid structure. The assignment may be iterative. For example, when there are 3012 patterns of the ID aa and 100 patterns of the ID bb, a first pattern, which is one of the patterns of the ID bb, is assigned to a grid at a position corresponding to coordinates of the first pattern, and then, a second pattern, which is one of the patterns of the ID aa, is assigned to a grid at a position corresponding to coordinates of the second pattern. The reason why the patterns of the ID with a lower frequency are first assigned to the grids is that the patterns of the ID with a higher frequency have a relatively high possibility of being assigned to grids through iteration. The assignment may be based on the pigeon-hole principle; however, example embodiments are not limited thereto.

Referring to FIG. 1 and FIG. 2D, when the patterns of IDs are assigned to grids by using the method described above, there may be patterns of IDs that are not assigned to the grids. For example, when trying to assign patterns of IDs to the grids, which are not yet assigned to grids, there may be a case where all grids are previously assigned, or a case where all patterns of IDs that have not been assigned to grids are located in previously assigned grids.

In this case, the pattern of the ID assigned to the grids are classified as selected patterns SP, the patterns of the IDs not assigned to the grids are classified as non-selected patterns NSP, distances (e.g., Euclidean and/or Manhattan distances) between the non-selected patterns NSP and the selected patterns SP are calculated for each ID, and the most distant non-selected patterns NSP may be assigned to grids. In this way, when the patterns associated with the ID, which are not assigned to grids, are later assigned to the grids, two or more patterns may be assigned to the same grid. Accordingly, when two or more patterns are assigned to the same grid, patterns of different IDs may be extracted and assigned.

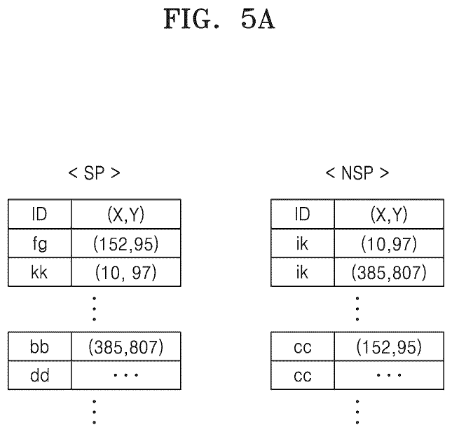

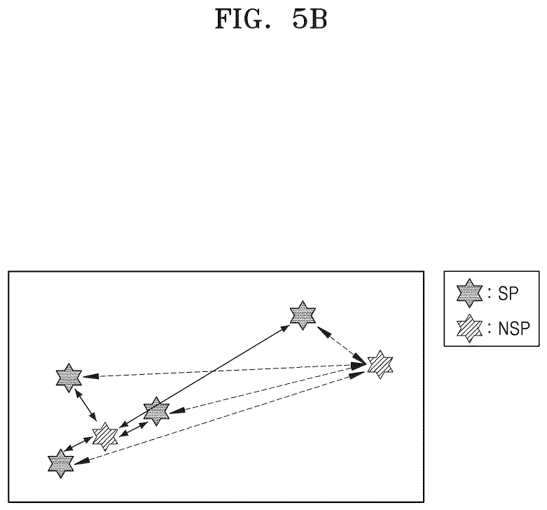

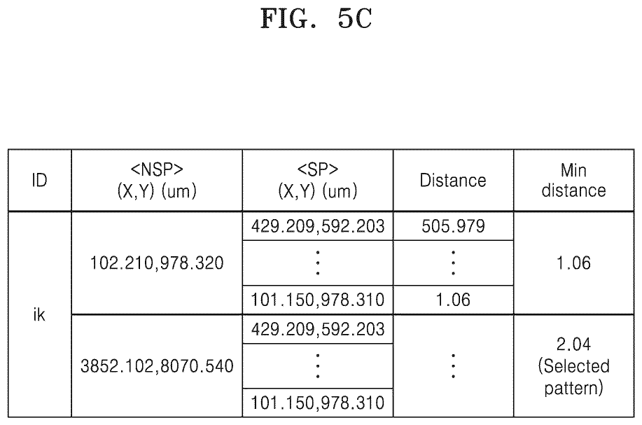

There may be patterns of IDs that are not assigned to grids; the concept of assigning the patterns of IDs, which are not assigned to grids, to the grids through distance calculation is described below in more detail with reference to FIG. 5A to FIG. 5C.

After an extracted pattern is assigned to a corresponding grid in a two-dimensional grid structure, at least some of the patterns assigned to the grid may be measured (S140). For example, patterns corresponding to the patterns of one layer of a full-chip may be formed on a substrate through an exposure process. Patterns formed on the substrate may be or include, for example, photo-resist (PR) patterns. In addition, patterns may be measured by a SEM. However, the measurement of patterns is not limited to the SEM. For example, instead of the SEM, another measurement performed by using an electron beam similar to the SEM may also be used to measure patterns. In addition, as described above, the patterns that are measured may be or include PR patterns, and accordingly, the measurement of patterns may be an after development inspection (ADI) measurement.

The semiconductor pattern measurement method according to various example embodiments may be performed by extracting patterns for each type by using a pattern reduction tool for specific or countless patterns of one of multiple layers of a full-chip, assigning IDs to the patterns for each type, assigning the patterns to grids according to the frequency of IDs, and measuring only the patterns assigned to the grids. Because the patterns assigned to the grids in this way include patterns of different IDs, the patterns assigned to the grids may more likely include all unique patterns requiring or expecting measurement. Alternatively or additionally, the patterns assigned to the grids may have certain distances therebetween based on the grids. Therefore, according to the semiconductor pattern measurement method of the embodiment, all types of patterns requiring or expecting measurement may be measured, while preventing or reducing the likelihood of and/or impact from metrology damage. That is, a problem, such as exclusion of important patterns of a high percentage from measurement, may not occur or may be less likely to occur.

For reference, in measurement using a SEM or measurement using an electron beam similar thereto, a phenomenon in which a measurement region of which image is to be acquired is damaged by a high voltage electron beam may be called SEM burn. In particular, the SEM burn may cause serious damage to an organic PR surface during ADI measurement shortly after a PR development process. The SEM burn is generally caused by overlapping measurement positions and repeated SEM measurement in the same region. Therefore, in order to prevent or reduce the SEM burn, measuring patterns at overlapped positions can be avoided.

Alternatively or additionally, as described above, the OPC technology may correct a mask pattern by considering the interference of a light source and the reaction with PR, and ADI measurement may be highly important in the OPC technology. This may be because the ADI measurement is to measure a critical dimension (CD) of a pattern after exposure and development of PR in a state where the influence of other semiconductor processes, such as etching, is excluded. Therefore, it can be important to measure patterns with a sufficient separation distance for accurate measurement. However, when there are N candidate patterns to be measured, the number of calculations on separation distances of the N candidate patterns is N*(N−1)/2, and a process of selecting a pattern to be measured has to be performed based on the separation distance, and accordingly, when the N value is very large, unnecessary resources may be consumed, and/or the calculation itself may not be performed due to an insufficient memory.

Accordingly, in the general semiconductor pattern measurement method, separation distances are calculated only for hundreds to thousands of patterns to be measured, and patterns that do not meet conditions are excluded, and/or a method of finding identical patterns based on geometry may be applied. However, when patterns are excluded, there may be a problem of missing patterns to be measured. In addition, the method of finding identical patterns based on geometry requires additional calculation for obtaining sufficient separation distances, and calculations for obtaining the sufficient separation distances for hundreds of millions of pattern coordinates in a full-chip level are currently impossible.

However, according to the semiconductor pattern measurement method of various example embodiments, some or all the problems described above may be solved or improved upon by measuring only the patterns assigned to grids by using the method described above. For example, a problem, such as SEM burn due to duplicate measurements, exclusion of patterns to be measured from measurement, and calculation on all separation distances between numerous patterns, may all be solved or improved upon.

Alternatively or additionally, the semiconductor pattern measurement method according to various example embodiments may be applied to all of the following measurement methods and/or may include all of corresponding methods. In particular, the semiconductor pattern measurement method according to various example embodiments may be applied to all measurement methods using devices that may damage PR with an electron beam or the equivalent, such as a SEM. Additionally or alternatively, the semiconductor pattern measurement method according to various example embodiments may be applied to measurement methods of all pattern types, such as contact/line & space. Additionally or alternatively, the first measurement method and the second measurement method may include all methods of obtaining separation distances by using assigned IDs and coordinates through clustering, pattern matching, ORC, and a method similar thereto. Additionally or alternatively, in relation to the third method, patterns may be assigned to grids for each ID by causing a full-chip to have a two-dimensional grid structure to obtain sufficient separation distances and computation speed. Additionally or alternatively, in relation to the fourth method, patterns of IDs that are not assigned to grids may be assigned to the grids by directly calculating distances from previously assigned patterns while obtaining sufficient separation distances.

FIG. 3A to FIG. 3C are ID tables specifically illustrating an operation of assigning IDs and an operation of assigning the IDs to grids which are included in the semiconductor pattern measurement method of FIG. 1. Descriptions made above with reference to FIG. 1 to FIG. 2D are briefly given or omitted.

Referring to FIG. 3A, an ID table may be generated by extracting patterns for each type by using a pattern reduction tool and by assigning IDs thereto, as described above with reference to FIG. 1 and FIG. 2A. As illustrated in FIG. 3A, the ID table may include IDs, X coordinates and Y coordinates of patterns (such as a center thereof), and the frequency of the IDs. In some cases, the X coordinates and Y coordinates of the patterns may be written in mm units. However, the X coordinates and Y coordinates of the patterns are not limited to the mm units. The X coordinates and Y coordinates may correspond to distance coordinates indicating distances from a reference point. In some cases the coordinates may be polar coordinates; example embodiments are not limited thereto.

Referring to FIG. 3B, after IDs are assigned to patterns for each type, a two-dimensional grid structure may be formed on a full-chip. For example, a two-dimensional grid structure with integer grid coordinates may be formed by dividing the X coordinates and Y coordinates of the patterns by 10 and rounding down may be applied thereto. In addition, in conversion to an integer form, not only rounding down, but also rounding up or rounding to a center or taking a ceiling and/or a floor may be applied. As a two-dimensional grid structure is formed on a full-chip, the distance coordinates of patterns in the ID table may be converted into grid coordinates. For example, when (1001.100,1002.100), which are distance coordinates of a pattern of the uppermost ID aa, are divided by 10 and rounded down, distance coordinates may be changed to (100,100) which are grid coordinates. In some cases, on a full-chip, the distance coordinates 1001.100 mm in the X direction and 1002.100 mm in the Y direction of the pattern of the uppermost ID aa may be changed to a 100th grid coordinate in the X direction and a 100th grid coordinate in the Y direction.

Referring to FIG. 3C, after a two-dimensional grid structure is formed on a full-chip and distance coordinates are changed to grid coordinates, IDs are sorted in order of the frequency; e.g., IDs are sorted in the ID table. For example, as illustrated in FIG. 3C, an ID with the lowest frequency may be placed at the top, and IDs may be placed in a lower portion in order of increasing frequency.

Thereafter, as described above, the patterns are extracted or sorted in order from the pattern of an ID with the lowest frequency to the pattern of an ID with the highest frequency, and the extracted patterns are assigned to grids of a corresponding grid structure. For example, in the ID table of FIG. 3C, a pattern of an uppermost ID fg is assigned to a grid of 152 and 95. Next, one of two patterns of an ID kk is assigned to a grid of 10 and 97. Subsequently, one of following patterns of the ID may be assigned to a corresponding grid.

When there are a plurality of patterns of an ID, one of the plurality of pattern of the ID located in a grid that does not overlap with the patterns previously assigned to another grid may be assigned to the grid. In addition, when there are a plurality of patterns of a certain ID and the plurality of patterns are located in the same grid as the patterns previously assigned to the grid (including a case where patterns are previously assigned to all grids), the patterns of the certain ID may not be immediately assigned to the grid. In this case, distance from the patterns previously assigned to grids may be calculated, and the furthest pattern among the patterns of the certain ID may be assigned to the grid. Descriptions thereof are made in more detail with reference to FIG. 5A to FIG. 5C.

In addition, patterns of different IDs may be assigned to respective grids of a two-dimensional grid structure. However, in some example embodiments, a plurality of patterns of the same ID may be assigned to grids at different positions. For example, when there are sufficient grids, patterns may be assigned to grids with different weights for each ID by considering one or more of the importance of a pattern of a corresponding ID, the frequency of IDs, and so on. For example, when a weight is set to about 1/100 of the frequency, 30 patterns may be assigned to a grid because the frequency of the ID aa is 3012 in the ID table of FIG. 3B, and one pattern may be assigned to a grid because the frequency of the ID bb is 100.

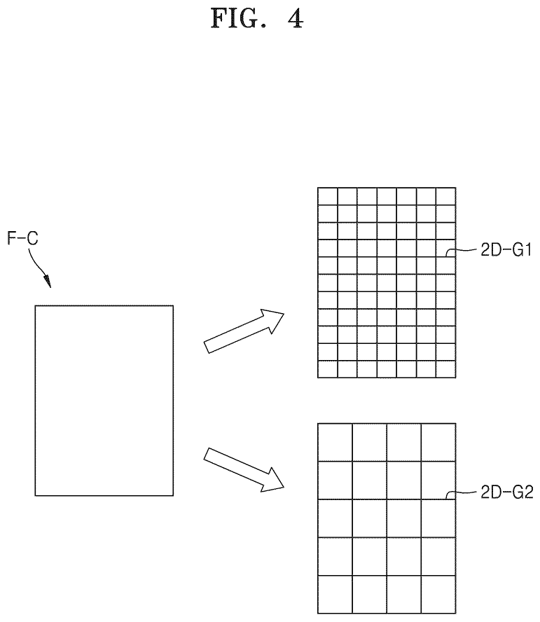

FIG. 4 is a conceptual diagram illustrating an operation of forming a two-dimensional grid structure which is included in the semiconductor pattern measurement method of FIG. 1. Descriptions made above with reference to FIG. 1 to FIG. 3C are briefly given or omitted.

Referring to FIG. 4, in the semiconductor pattern measurement method according to various example embodiments, a two-dimensional grid structure may be formed in various sizes on the full-chip F-C in operation S120 of forming the two-dimensional grid structure on the full-chip F-C. For example, the two-dimensional grid structure may be formed to include small-sized grids, such as a two-dimensional grid structure 2D-G1 in the upper right of FIG. 4, or may be formed to include large-sized grids, such as a two-dimensional grid structure 2D-G2 in the lower right of FIG. 4. For example, a size of the two-dimensional grid structure may be adjusted by values dividing an X coordinate and a Y coordinate. Specifically, when the X coordinate and Y coordinate are divided by 10, a width of each of grids in the X direction and Y direction may be about 10 mm. In addition, when the X coordinate and Y coordinate are divided by 50, a width of each of grids in the X direction and Y direction may be about 50 mm, and when the X coordinate and Y coordinate are divided by 2, a width of each of the grids in the X direction and Y direction may be about 2 mm. Although the grid may be square, example embodiments are not limited thereto, and a dimension in the X direction of a grid may be less than or greater than that of the Y direction of the grid.

In addition, when the sizes of the grids are too large, the number of patterns located in the same grid increases, and accordingly, in operation S130 of assigning IDs to grids, separation distances between the patterns have to be calculated and assigned to the grids. Therefore, a problem may occur in which the amount of calculation on the separation distances increases. Alternatively or additionally, when the sizes of the grids are reduced, patterns for each ID may be assigned to all grids, and there may be no need to calculate separately the separation distances. However, as the grid size is reduced, separation distances between patterns on adjacent grids may be less than a cutline of a separation distance required for measurement, and again, a problem, such as SEM burn due to measurement of overlapped regions, may occur again. Therefore, according to the semiconductor pattern measurement method of various example embodiments, sizes of grids may be appropriately selected by considering one or more of an arrangement distribution of patterns, a cutline of the required separation distance, and so on.

FIG. 5A to FIG. 5C are ID tables and a conceptual diagram illustrating a method of assigning patterns of IDs to grids when there are patterns of IDs not assigned to the grids, in relation to the operation S130 of assigning the patterns of IDs to the grids, in the semiconductor pattern measurement method of FIG. 1. Descriptions made above with reference to FIG. 1 to FIG. 3C are briefly given or omitted.

Referring to FIG. 5A, in operation S130 of assigning patterns of IDs to grids, when there are patterns of IDs not assigned to the grids, patterns of IDs assigned to the grids are classified as selected patterns SP, and patterns of IDs not assigned to the grids are classified as non-selected patterns NSP. In FIG. 5A, an ID table indicated by <SP> includes patterns of IDs assigned to grids, for example, the selected patterns SP, and an ID table indicated by <NSP> includes patterns of IDs not assigned to the grids, for example, the non-selected patterns NSP. For reference, the patterns of IDs are assigned to the grids in order of decreasing frequency, and accordingly, each ID in the ID table indicated by <NSP> may include a plurality of patterns. A size of the ID table indicated by <SP> may be less than a size of the ID table indicated by <NSP>.

Referring to FIG. 5B, in order to assign at least one of the patterns NSP of IDs not assigned to the grids, it may be necessary to calculate separation distances between the patterns SP previously assigned to the grids and the patterns NSP not assigned to the grids. Here, the separation distances may be Euclidean distances; however, example embodiments are not limited thereto, and in some cases the separation distances may be Manhattan distances. When the separation distances are Euclidean distances, in a two-dimensional plane, when a distance between two patterns in the X direction is referred to as dx and a distance between two patterns in the Y direction is referred to as dy, a separation distance between the two patterns may be calculated as (dx²+dy²)^{1/2}. Among the patterns of IDs not assigned to the grids, a pattern with the greatest value obtained by calculating the separation distance may be assigned to the grid.

Referring to FIG. 5C, one of two patterns of an ID ik may be assigned to grids by calculating a separation distance between the patterns SP assigned to the grids.

The uppermost pattern of the ID ik has distance coordinates of (102.210, 978.320), and when there are N patterns (SP) assigned to the grids, N separation distances are calculated, and the shortest distance among the N separation distances is 1.06. Next, the second pattern of the ID ik may have distance coordinates of (3852.102, 8070.540), and N separation distances to the patterns SP assigned to N grids may be calculated, and the shortest distance among the N separation distances may be 2.04. Therefore, by comparing shortest distances of the separation distances with each other, the second pattern of the ID ik with the greatest value may be selected and assigned to the grid.

Alternatively or additionally, in calculating the separation distances, when there is a risk that the amount of calculation increases, the number of patterns NSP not assigned to the grids may be limited for each ID. For example, when the number of patterns is limited to 2 for each ID and there are 100 patterns of a certain ID not assigned to the grid, for only two among the patterns of a certain ID, the separation distances to patterns SP assigned to the grid may be calculated. Also, the number and range of patterns SP assigned to the grids may be limited based on distance coordinates of the patterns NSP not assigned to the grids.

For reference, by comparing the semiconductor pattern measurement method according to the present embodiment with a general method of extracting patterns with a preset separation distance by using the X coordinates and Y coordinates of all patterns, whether calculation may be performed on actual patterns of a full-chip may be checked. As a result, according to the semiconductor pattern measurement method of various example embodiments, it can be seen that, when 135 pieces of million polygon data are input, calculation operation operate normally with a runtime of about an hour. In contrast to this, according to the method of calculating the separation distance by using the X coordinates and Y coordinates of all patterns, even for 1 million patterns or more, calculation operation do not operate normally due to an insufficient memory.

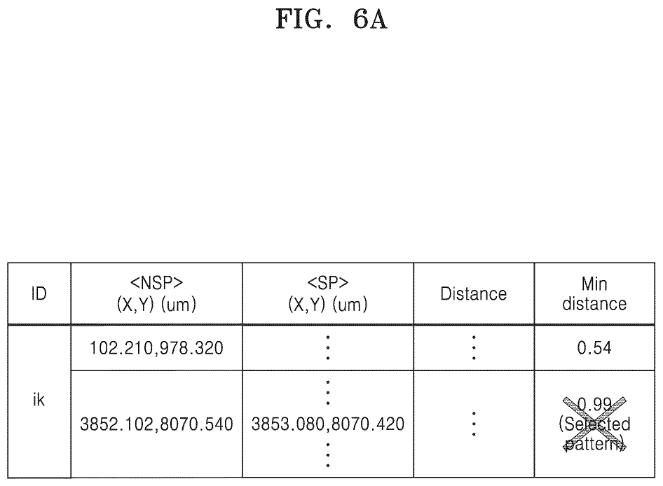

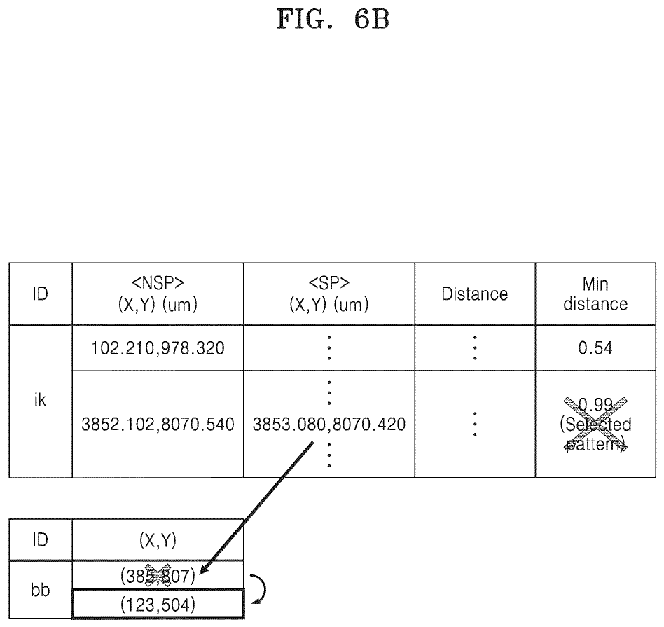

Through the distance calculation method described above, patterns of IDs not assigned to grids may be assigned to the grids. However, a case may occur in which the greatest value selected by comparison between the shortest distances is less than a cutline for the required separation distance. In this case, the problem may be solved by replacing the patterns SP which are assigned to grids and used to calculate the separation distance. This is described below in more detail with reference to FIGS. 6A and 6B.

FIG. 6A and FIG. 6B are ID tables illustrating exceptional cases of a method of assigning patterns of IDs to grids through the distance calculation of FIG. 5A to FIG. 5C. Descriptions made above with reference to FIG. 1 to FIG. 5C are briefly given or omitted.

Referring to FIG. 6A, when the shortest distances among the separation distances between two patterns of the ID ik in the ID table of FIG. 5C and the patterns SP assigned to the grids are 0.54 and 0.99, 0.99 may correspond to the greatest value. However, in order to avoid duplicate measurements, when a cutline of the required separation distances is 1 mm, the pattern may not be assigned to a grid because 0.99 mm is less than 1 mm.

Referring to FIG. 6B, when the pattern SP, which is assigned to a grid and has distance coordinates of (3853.080, 8070.420), is used to calculate the value of 0.99, and when another pattern of the same ID, for example, the ID bb is in a different position, the problem of violation of the cutline of separation distances may be solved by replacing the pattern SP assigned to the grid with a pattern of the same ID in another position. For example, by replacing the pattern SP assigned to a grid at coordinates (385, 807) with another pattern of the same ID assigned to a grid at coordinates (123, 504), the problem of violation of the cutline of separation distances may be solved. However, separation distances between the pattern SP, which is replaced and newly assigned to a grid, and surrounding patterns have to be greater than or equal to the cutline of separation distances.

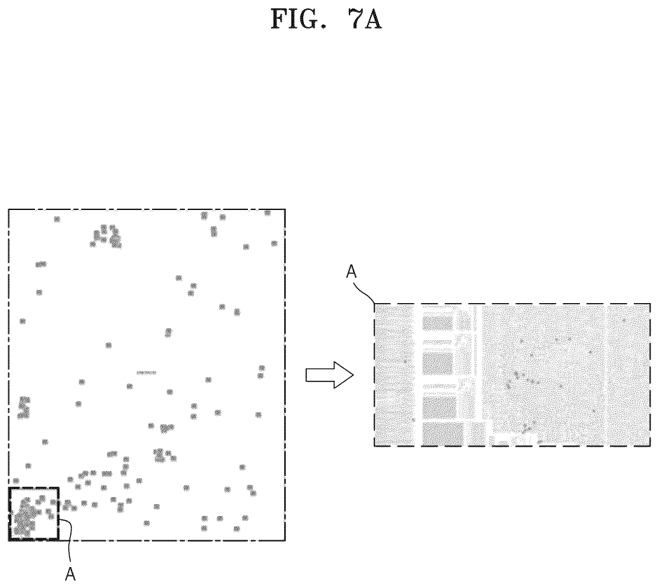

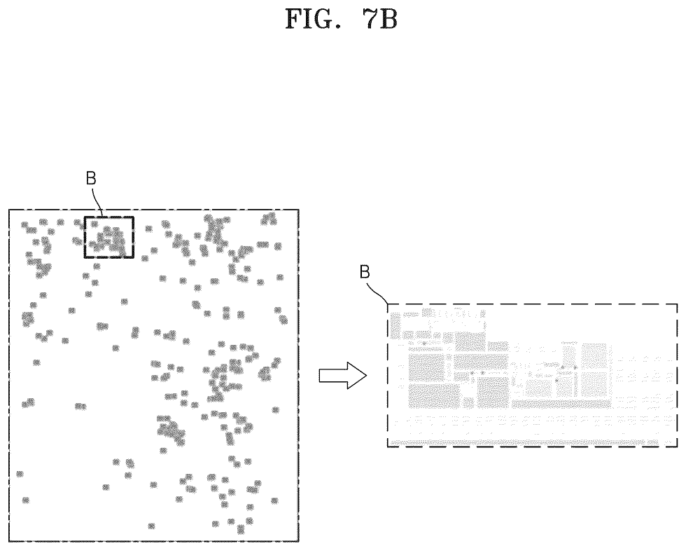

FIG. 7A and FIG. 7B are conceptual views and enlarged views illustrating distributions of patterns of measurement targets, in the semiconductor pattern measurement method according to a comparative embodiment and a semiconductor pattern measurement method according to various example embodiments.

Referring to FIG. 7A, in the semiconductor pattern measurement method according to the comparative example, the drawing on the left shows patterns of measurement targets in a full-chip as small black squares. Also, the drawing on the right part shows an enlarged view of a portion A where the patterns of the measurement targets in the full-chip on the left are concentrated, and the small black dots also represent the patterns of the measurement targets. As may be seen from FIG. 7A, the patterns of measurement targets overlap each other. Therefore, there is a high possibility that SEM burn occurs. Also, the semiconductor pattern measurement method according to the comparative example has a tendency for the patterns of measurement targets to be concentrated at a random or certain position, and accordingly, in an actual measurement using a SEM, a problem, such as exclusion of important patterns of a high percentage from measurement, may occur.

Referring to FIG. 7B, in the semiconductor pattern measurement method according to various example embodiments, the drawing on the left shows patterns of measurement targets in a full-chip as small black squares. Also, the drawing on the right part shows an enlarged view of a portion B where the patterns of the measurement targets in the full-chip on the left are concentrated, and the small black dots also represent the patterns of the measurement targets. As may be seen from FIG. 7B, the patterns of measurement targets are arranged with sufficient separation distances. Therefore, there is a lower possibility that SEM burn occurs. Also, in the semiconductor pattern measurement method according to the present embodiment, all patterns may be measured by obtaining sufficient separation distances, and thus, a problem, such as exclusion of important patterns of a high percentage from measurement, may not occur or may be less likely to occur.

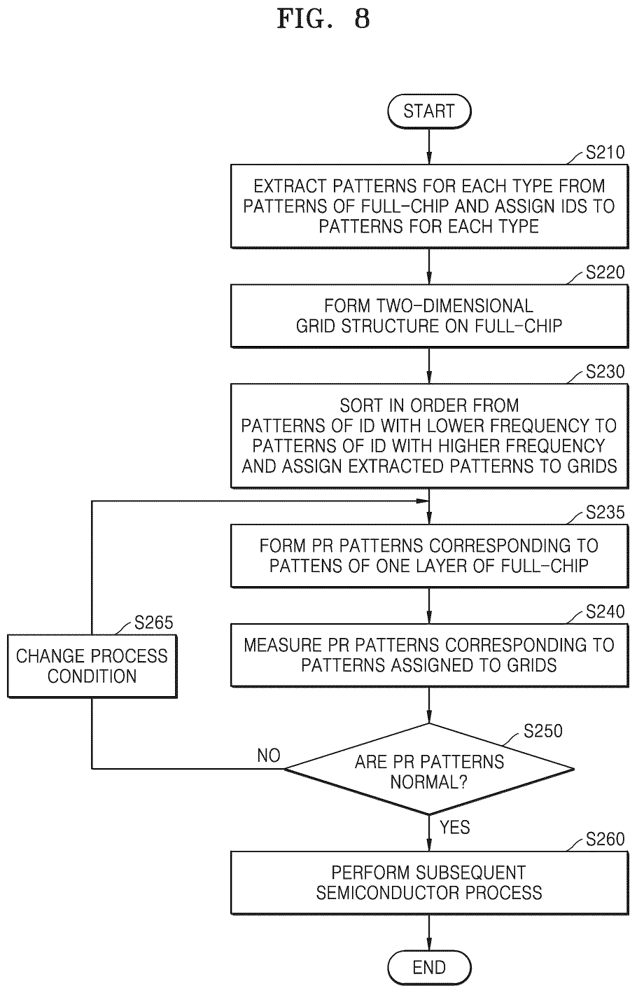

FIG. 8 is a flowchart schematically illustrating a semiconductor device manufacturing method including a semiconductor pattern measurement method, according to some example embodiments. Descriptions are made with reference to FIG. 1 to FIG. 2D, and descriptions made above with reference to FIG. 1 to FIG. 7B are briefly given or omitted.

Referring to FIG. 8, the semiconductor device manufacturing method including the semiconductor pattern measurement method according to various example embodiments (hereinafter, simply referred to as a “semiconductor device manufacturing method”) sequentially performs operation S210 of assigning an ID to operation S230 of assigning the ID to a grid. Operation S210 of assigning an ID to operation S230 of assigning the ID to a grid are respectively identical to operation S110 of assigning an ID to operation S130 of assigning the ID to a grid included in the semiconductor pattern measurement method of FIG. 1.

Next, a PR pattern corresponding to patterns of one of multiple layers of a full-chip is formed (S235). The PR pattern may be formed on a substrate. Here, the substrate may be a test wafer, which is a temporary wafer only for forming the PR pattern. The test wafer may not have other patterns below the PR pattern. However, in some example embodiments, other patterns may be below the PR pattern even in the test wafer. In addition, the substrate may be a device wafer in which actual devices are formed. The device wafer may have other patterns below the PR pattern.

The PR pattern may be formed by applying PR on the substrate through a spin coating process or so on, and then performing an exposure process and a development process for the PR. The exposure process may be performed by using, for example, a deep ultraviolet (DUV) or extreme ultraviolet (EUV_light source. However, the light source for the exposure process is not limited to the light sources described above.

After the PR pattern is formed, the PR pattern corresponding to a pattern assigned to a grid may be measured (S240). The PR pattern may be measured by using a SEM or an electron-beam similar thereto. In addition, measurement of the PR pattern may correspond to ADI measurement. In the semiconductor device manufacturing method according to various example embodiments, only PR patterns corresponding to patterns assigned to grids may be measured. Accordingly, the measured PR patterns may be spaced apart from each other based on the grids, and thus, measurement damage, such as SEM burn, may be prevented. Also, patterns of each ID are assigned to grids in a reasonable manner, and accordingly, all types of patterns that require measurement may be measured. That is, a problem, such as exclusion of important patterns of a high percentage from measurement, may not occur or may be less likely to occur.

After the PR patterns are measure, whether the PR patterns are normal may be determined. Whether the PR patterns are normal may be determined through ADI evaluation. For example, the ADI evaluation may include various factors, such as shapes of the PR patterns, a CD, and an interval between adjacent PR patterns.

When the PR patterns are normal (YES), a subsequent semiconductor process is performed (S260). Here, the subsequent semiconductor process may include various processes. For example, the subsequent semiconductor process may include a deposition process, an etching process, an ion process, a cleaning process, and so on. Also, the subsequent semiconductor process may include a singulation process for individualizing a device wafer into respective semiconductor chips, a test process for testing the respective semiconductor chips, and a packaging process for packaging the respective semiconductor chips. A semiconductor device may be completed through the subsequent semiconductor process for a device wafer.

In addition, the subsequent semiconductor process may include a process for patterns of the next layer on one layer of a full-chip corresponding to the PR patterns. The process for the patterns of the next layer of the full-chip may include a measurement process for patterns of the next layer. Also, the semiconductor pattern measurement method described above may be applied to the measurement process for the patterns of the next layer.

When the PR patterns are not normal (NO), process conditions are changed (S265), and the process proceeds to an operation of forming the PR patterns (S235). Here, the process conditions may include a PR material, an exposure process condition, a development process condition, and so on. In the PR pattern formation operation (S235), the PR patterns may be formed again by applying the changed process conditions.

As described above, inventive concepts are described with reference to the embodiments illustrated in the drawings, and the embodiments are merely illustrative, and those skilled in the art will understand that various modifications and other equivalent embodiments may be derived therefrom. Therefore, the true scope of technical protection of the inventive concept should be determined by the technical idea of the attached claims.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., ±10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., ±10%).

While inventive concepts have been particularly shown and described with reference to various embodiments thereof, it will be understood that various changes in form and details may be made therein without departing from the spirit and scope of the following claims. Additionally, example embodiments are not necessarily mutually exclusive with one another. For example, some example embodiments may include one or more features described with reference to one or more figures, and may also include one or more other features described with reference to one or more other figures.

What is claimed is:

1. A semiconductor pattern measurement method comprising:
extracting patterns for each type from patterns of a full-chip stored in a database;
assigning an identification (ID) to the patterns;
forming a two-dimensional grid structure on the full-chip;
sorting the patterns in order from a pattern of the ID with a lowest frequency to a pattern of the ID with a highest frequency;
assigning the sorted patterns to corresponding grids of the two-dimensional grid structure; and
measuring the sorted patterns assigned to the grids,
wherein, in the measuring of the sorted patterns, a separation distance is set between patterns measured based on the grids.

2. The semiconductor pattern measurement method of claim 1, wherein, in the assigning of the ID, the patterns for each type are extracted by using at least one of a clustering tool, a pattern matching tool, and an optical rule check (ORC) tool.

3. The semiconductor pattern measurement method of claim 1, wherein
the database includes information on patterns of multiple layers of the full-chip, and
in the assigning of the ID, the patterns for each type are extracted from patterns of any one layer among the multiple layers of the full-chip.

4. The semiconductor pattern measurement method of claim 1, wherein, in the assigning of the sorted patterns to the corresponding grids, patterns of an ID in positions corresponding to coordinate positions of the grids are assigned to the grids.

5. The semiconductor pattern measurement method of claim 4, wherein, in response to two or more patterns assigned to one grid, patterns of different IDs are assigned.

6. The semiconductor pattern measurement method of claim 1, wherein, in the forming of the two-dimensional grid structure, the two-dimensional grid structure is formed by setting widths of the grids into equal widths in a first direction and a second direction perpendicular to the first direction.

7. The semiconductor pattern measurement method of claim 1, wherein, in the assigning of the extracted patterns to the corresponding grids,
in response to patterns of IDs not assigned to the grids, the patterns of IDs assigned to the grids are classified as selected patterns, and the patterns of the IDs not assigned to the grids are classified as non-selected patterns, and
distances to the selected patterns are calculated for each ID of the non-selected patterns, and a non-selected pattern based on a farthest non-selected pattern is assigned to the grid.

8. The semiconductor pattern measurement method of claim 7, wherein, in response to an ID of the non-selected pattern being referred to as a first ID and the first ID includes a plurality of first patterns, shortest distances between each of the first patterns and the selected patterns are calculated, and the first pattern corresponding to a greatest value of the shortest distances is assigned to the grid and is the farthest non-selected pattern.

9. The semiconductor pattern measurement method of claim 7, wherein, in response to the farthest non-selected pattern being referred to as a first pattern and a selected pattern contributing to selection of the first pattern being referred to as a second pattern, and
in response to a distance between the first pattern and the second pattern being less than a cutline of a set separation distance, the second pattern is replaced with a pattern of the same ID as the second pattern located in a different position.

10. The semiconductor pattern measurement method of claim 1, wherein a weight is set for each frequency of the IDs and at least one patterns of the ID is assigned to the grids depending on the weight.

11. The semiconductor pattern measurement method of claim 1, wherein, in the measuring of the patterns assigned to the grids, the patterns are measured by using at least one of a scanning electron microscope (SEM) or an electron beam other than the SEM.

12. The semiconductor pattern measurement method of claim 1, wherein, in the measuring of the patterns assigned to the grids, an after development inspection (ADI) measurement is performed.

13. A semiconductor pattern measurement method comprising:
extracting, by a pattern reduction tool, patterns for each type from patterns of one layer among multiple layers of a full-chip stored in a database and assigning an identification (ID) to the patterns;
forming a two-dimensional grid structure on the full-chip;
sorting the patterns in order from a pattern of the ID with a lowest frequency to a pattern of the ID with a highest frequency;
assigning the sorted patterns to corresponding grids of the two-dimensional grid structure; and
measuring, by a scanning electron microscope (SEM), a photoresist (PR) pattern corresponding to the patterns assigned to the grids, wherein
in the assigning of the sorted patterns to the corresponding grids, in response to patterns of IDs not being assigned to the grids, the patterns of the ID assigned to the grids are classified as selected patterns, and the patterns of the IDs not assigned to the grids are classified as non-selected patterns, and
distances to the selected patterns are calculated for each ID of the non-selected patterns, and a farthest non-selected pattern is assigned to the grid.

14. The semiconductor pattern measurement method of claim 13, wherein, in response to an ID of the non-selected pattern being referred to as a first ID and the first ID includes a plurality of first patterns, shortest distances between each of the first patterns and the selected patterns are calculated, and the first pattern corresponding to a greatest value of the shortest distances is assigned to the grid.

15. The semiconductor pattern measurement method of claim 14, wherein, in response to the farthest non-selected pattern being referred to as a first pattern and the selected pattern contributing to selection of the first pattern is referred to as a second pattern, and in response to a distance between the first pattern and the second pattern being less than a cutline of a set separation distance, the second pattern is replaced with a pattern of the same ID as the second pattern located in a different position.

16. A semiconductor device manufacturing method comprising:
extracting, by a pattern reduction tool, patterns for each type from patterns of one layer among multiple layers of a full-chip stored in a database and assigning an identification (ID) to the patterns;
forming a two-dimensional grid structure on the full-chip; sorting the patterns in order from a pattern of the ID with a lowest frequency to a pattern of the ID with a highest frequency, and assigning the sorted patterns to corresponding grids of the two-dimensional grid structure;
forming photoresist (PR) patterns corresponding to the patterns of the one layer;
measuring the PR patterns corresponding to the patterns assigned to the grids;
determining whether the PR patterns are normal; and
performing a subsequent semiconductor process in response to the PR patterns being normal,
wherein, in the measuring of the PR patterns, a separation distance is set between the PR patterns measured based on the grids.

17. The semiconductor device manufacturing method of claim 16, wherein
the pattern reduction tool includes at least one of a clustering tool, a pattern matching tool, and an ORC tool, and
in the assigning of the sorted patterns to the corresponding grids, patterns of an ID in positions corresponding to coordinate positions of the grids are extracted and assigned to the grids.

18. The semiconductor device manufacturing method of claim 16, wherein, in the assigning of the sorted patterns to the corresponding grids,
in response to patterns of IDs not assigned to the grids, the patterns of the ID assigned to the grids are classified as selected patterns, and the patterns of the IDs not assigned to the grids are classified as non-selected patterns, and
distances to the selected patterns are calculated for each ID of the non-selected patterns, and a farthest non-selected pattern is assigned to the grid.

19. The semiconductor device manufacturing method of claim 18, wherein, in response to an ID of the non-selected pattern being referred to as a first ID and the first ID includes a plurality of first patterns, shortest distances between each of the first patterns and the selected patterns are calculated, and the first pattern corresponding to a greatest value of the shortest distances is assigned to the grid.

20. The semiconductor device manufacturing method of claim 16, wherein, in response to the PR patterns not being normal, process conditions are changed, and then other PR patterns are formed.
